(19) United States
(12) Patent Application Publication
(10) Pub. No.: US 2023/0069377 A1
(43) Pub. Date: Mar. 2, 2023

(54) ELECTRIC METER INTERRUPT DEVICE

(71) Applicant: ALIVE Industries, Inc., Escondido, CA (US)

(72) Inventors: Adam HAMMILL, Escondido, CA (US); Daniel WERT, Escondido, CA (US)

(73) Assignee: ALIVE Industries, Inc., Escondido, CA (US)

(21) Appl. No.: 17/823,871

(22) Filed: Aug. 31, 2022

Related U.S. Application Data
(60) Provisional application No. 63/239,731, filed on Sep. 1, 2021.

(51) Int. Cl. G01R 21/133

(52) U.S. Cl. CPC G01R 21/1335

(57) ABSTRACT

The electric meter interrupt device provides a means of connecting an external transfer switch and renewable and/or backup power sources at the nodes between the utility meter and the main panel. This method allows grid disconnect and whole home backup that almost never requires modification of an electrical panel or relocation of loads, using a UL approved transfer switch and overcurrent protection device. The device routes the entirety of available utility power away from the electric meter and then back into the electrical panel, allowing unprecedented control and capacity. Creating this “true bypass” allows for the introduction of renewable energy sources, battery power, and/or generator power sources.

### CROSS-REFERENCE TO RELATED APPLICATIONS

This application is a non-provisional of and claims priority to U.S. Provisional Application No. 63/239,731, titled “Electric Meter Interrupt Device”, filed Sep. 1, 2021, which is incorporated by reference herein in its entirety.

### FIELD OF INVENTION

This invention relates to devices, systems, and methods of using said devices and systems, for facilitating all-load backup and grid disconnect for residential, commercial, and agricultural electrical customers.

### BACKGROUND OF THE INVENTION

Adding solar power or batteries to any grid-connected electrical system often requires up-sizing of electrical panels or de-rating of main breakers to accommodate the additional power. Many systems require installation of an additional subpanel and relocation of breakers and loads to separate them from the main panel for backup purposes, or to provide capacity for the additional new power sources. While many meter adapters exist, none of them are “true bypass” devices.

Traditional backup systems require a breaker to introduce auxiliary power to an electrical panel. which is limiting (1) by taking up physical space in the electrical panel, and (2) by taking up electrical capacity of the bus bar, which can only support source breakers (incoming power) of up to 120% of the bus bar capacity (i.e., incoming power from the main breaker plus input from renewable and/or backup power sources) according to electrical code. Due to these limitations, some :labor- and material-intensive steps need to be taken to add auxiliary power to a. system. These steps include such things as panel upgrades (to increase the bus bar capacity), main breaker de-rates (to create more capacity on the bus bar for additional inputs) and/or adding sub-panels (to increase bus bar size and/ or to move loads away from the all-in-one panel so that the power can be interrupted by the transfer switch/gateway).

Based on the foregoing, there is a need in the art for a device/system, and methods thereof, that reduces the labor involved in renewable and/or backup power source installations for utility customers with single-phase, non-CT-metered electrical service, by creating not only a new location for the addition of new power sources, but a means by which the entire main panel can be safely backed up in an outage with drastically less labor.

### SUMMARY OF THE INVENTION

Preferred embodiments include an electric meter interrupt device (MID) comprising: a housing; a first set of electrical stabs and a second set of electrical stabs disposed at a first side of the housing; a first set of electrical receptacles and a second set of electrical receptacles disposed at a second side of the housing, wherein the first set of electrical stabs are in electrical communication with the first set of electrical receptacles, wherein the MID is configured to electrically couple to an outbound pair of electrical wires, each being in electrical communication with a corresponding receptacle of the second set of electrical receptacles, and wherein the MID is configured to electrically couple to an inbound pair of electrical wires, each being in electrical communication with a corresponding stab of the second set of electrical stabs.

The MIDs provided herein can be configured to mount between an electrical panel and an electric meter, wherein the MID is configured to receive electricity from the electrical panel, wherein the electricity received into the MID from the electrical panel is routed directly to the electric meter, wherein electricity output by the electric meter is routed through the MID to a transfer switch and then back through the MID to the electrical panel.

The MIDs provided herein can have a first and second set of MID stabs are constructed and oriented to mimic metal stabs that protrude from the rear side of an electric meter such they are configured to operably couple with electrical panel receptacles, and wherein the first and second set of MID receptacles are constructed and oriented to mimic electrical panel receptacles such that they are configured to operably couple and receive the electric meter stabs.

The MIDs provided herein can include embodiments wherein the size of each of the inbound wires and outbound wires are selected from the group consisting of 0000 AWG, 000 AWG, 00 AWG, 0 AWG, 1 AWG, 2 AWG, 3 AWG, and 4 AWG.

Preferred embodiments include an electric meter interrupt system comprising: a meter socket having receptacles, and positioned within and operably coupled to either a meter-only box or a main panel; an electrical power grid operably coupled to the meter socket; an electrical meter having stabs; an electric meter interrupt device (MID) comprising: a housing; a first set of electrical stabs and a second set of electrical stabs disposed at a first side of the housing, wherein the first and second set of MID electrical stabs are constructed and oriented to mimic the stabs of the electrical meter, and are operably coupled to the receptacles in the meter socket; a first set of electrical receptacles and a second set of electrical receptacles disposed at a second side of the housing, wherein the first and second set of MID receptacles are constructed and oriented to mimic the meter socket receptacles, and are operably coupled to the electric meter stabs, and wherein the first set of MID electrical stabs are in electrical communication with the first set of MID electrical receptacles; wherein the second set of electrical receptacles are electrically couple to an outbound pair of electrical wires, each being in electrical communication with a corresponding receptacle of the second set of electrical receptacles, and the second set of electrical stabs are electrically couple to an inbound pair of electrical wires, each being in electrical communication with a corresponding stab of the second set of electrical stabs.

Preferably the systems herein include embodiments wherein the meter socket is positioned within the main panel that is operably coupled to a building's circuits and the MID is configured to receive electricity from the main panel through its first set of electrical stabs, and then deliver the electricity directly to the electric meter through the MID's first set of receptacles; and wherein electricity output by the electric meter is configured to route back through the MID to a transfer switch via the second set of MID receptacles/outbound pair of electrical wires and then from the transfer switch back through the MID via the second set of MID stabs/inbound pair of electrical wires, and then to the main panel.

Preferably the systems herein include embodiments wherein the transfer switch is operably coupled to an auxiliary power source and configured such as to either a) allow the electricity from the auxiliary power source to flow to the main panel or back-feed to the grid during non-outage conditions, or b) disconnect the auxiliary power source from the grid during a power outage to prevent back-feed, thereby allowing the auxiliary power to energize the main panel and the coupled building circuits.

Preferably the systems herein include embodiments wherein the transfer switch ability to connect and disconnect to the grid can be an automatic or manual mechanism.

Preferably the systems herein include embodiments wherein the auxiliary power source is selected from the group consisting of a solar photovoltaic and a battery.

Preferably the systems herein include embodiments wherein the meter socket is positioned within the meter-only box which in turn is operably coupled to the main panel that is operably coupled to a building's circuits; and the MID is configured to receive electricity from the meter-only box through its first set of electrical stabs, and then deliver the electricity directly to the electric meter through the MID's first set of receptacles; and wherein electricity output by the electric meter is configured to route back through the MID to a transfer switch via the second set of MID receptacles/outbound pair of electrical wires and then from the transfer switch back through the MID via the second set of MID stabs/inbound pair of electrical wires, and then to the meter-only box and then onto the main panel and the building's circuits.

A method of installing a MID can include: providing a meter socket having receptacles and operably coupled to an electrical power grid and positioned within and operably coupled to either a meter-only box or a main panel; providing an electrical meter having stabs; providing a Meter Interrupt Device (MID) comprising: a housing; a first set of electrical stabs and a second set of electrical stabs disposed at a first side of the housing, wherein the first and second set of MID electrical stabs are constructed and oriented to mimic the stabs of the electrical meter, such as to operably couple to the receptacles in the meter socket; a first set of electrical receptacles and a second set of electrical receptacles disposed at a second side of the housing, wherein the first and second set of MID receptacles are constructed and oriented to mimic the meter socket receptacles, such as to operably couple to the electric meter stabs, and wherein the first set of MID electrical stabs are in electrical communication with the first set of MID electrical receptacles; wherein the second set of electrical receptacles are electrically couple to an outbound pair of electrical wires, each being in electrical communication with a corresponding receptacle of the second set of electrical receptacles, and the second set of electrical stabs are electrically couple to an inbound pair of electrical wires, each being in electrical communication with a corresponding stab of the second set of electrical stabs; inserting the MID into the meter socket by coupling the MID stabs into the receptacles of the meter socket; and coupling the electric meter to the MID by coupling the stabs of the electric meter into the receptacles of the MID.

Preferably the methods herein include embodiments wherein the meter socket is positioned within the main panel that is operably coupled to a building's circuits and the MID is configured to receive electricity from the main panel through its first set of electrical stabs, and then deliver the electricity directly to the electric meter through the MID's first set of receptacles; and wherein electricity output by the electric meter is configured to route back through the MID to a transfer switch via the second set of MID receptacles/outbound pair of electrical wires and then from the transfer switch back through the MID via the second set of MID stabs/inbound pair of electrical wires, and then to the main panel.

Preferably the methods herein include embodiments wherein the transfer switch is operably coupled to an auxiliary power source and configured such as to either a) allow the electricity from the auxiliary power source to flow to the main panel or back-feed to the grid during non-outage conditions, or b) disconnect the auxiliary power source from the grid during a power outage to prevent back-feed, thereby allowing the auxiliary power to energize the main panel and the coupled building circuits.

Preferably the methods herein include embodiments wherein the transfer switch ability to connect and disconnect to the grid can be an automatic or manual mechanism.

Preferably the methods herein include embodiments wherein the auxiliary power source is selected from the group consisting of a solar photovoltaic and a battery.

Preferably the methods herein include embodiments wherein the meter socket is positioned within the meter-only box which in turn is operably coupled to the main panel that is operably coupled to a building's circuits; and the MID is configured to receive electricity from the meter-only box through its first set of electrical stabs, and then deliver the electricity directly to the electric meter through the MID's first set of receptacles; and wherein electricity output by the electric meter is configured to route back through the MID to a transfer switch via the second set of MID receptacles/outbound pair of electrical wires and then from the transfer switch back through the MID via the second set of MID stabs/inbound pair of electrical wires, and then to the meter-only box and then onto the main panel and the building's circuits.

The foregoing, and other features and advantages of the invention, will be apparent from the following, more particular description of the preferred embodiments of the invention, the accompanying drawings, and the claims.

### BRIEF DESCRIPTION OF THE DRAWINGS

For a more complete understanding of the present invention, the objects and advantages thereof, reference is now made to the ensuing descriptions taken in connection with the accompanying drawings briefly described as follows.

FIG. 1 shows a front view of the device, according to an embodiment of the present invention;

FIG. 2 shows a rear view of the device, according to an embodiment of the present invention;

FIG. 3 shows the device in use with the electrical panel and electric meter, according to an embodiment of the present invention;

FIG. 4 is a flow chart that outlines the flow of electricity in existing systems;

FIG. 5 illustrates the flow of electricity received into the electrical panel from the utility line, according to an embodiment of the present invention; and

FIG. 6 is a flow chart that outlines the flow of electricity received into the electrical panel from the utility line, according to an embodiment of the present invention.

FIG. 7 shows an exploded view of an embodiment of the device in use with a meter-only box and electric meter, according to an embodiment of the present invention;

FIG. 8 shows an assembled view of an embodiment of the device in use with a meter-only box and electric meter, according to an embodiment of the present invention;

FIG. 9 is a flow chart that outlines the flow of electricity received into a meter-only box from the utility line, according to an embodiment of the present invention.

### DETAILED DESCRIPTION OF PREFERRED EMBODIMENTS

In the following detailed description, reference is made to the accompanying drawings which form a part hereof, and in which are shown by way of illustration embodiments that may be practiced. It is to be understood that other embodiments may be utilized and structural or logical changes may be made without departing from the scope. Therefore, the following detailed description is not to be taken in a limiting sense, and the scope of embodiments is defined by the appended claims and their equivalents.

Various operations may be described as multiple discrete operations in turn, in a manner that may be helpful in understanding embodiments; however, the order of description should not be construed to imply that these operations are order dependent.

The description may use perspective-based descriptions such as up/down, back/front, and top/bottom. Such descriptions are merely used to facilitate the discussion and are not intended to restrict the application of disclosed embodiments.

The terms “coupled” and “connected,” along with their derivatives, may be used. It should be understood that these terms are not intended as synonyms for each other. Rather, in particular embodiments, “connected” may be used to indicate that two or more elements are in direct physical contact with each other. “Coupled” may mean that two or more elements are in direct physical contact. However, “coupled” may also mean that two or more elements are not in direct contact with each other, but yet still cooperate or interact with each other.

For the purposes of the description, a phrase in the form “A/B” or in the form “A and/or B” means (A), (B), or (A and B). For the purposes of the description, a phrase in the form “at least one of A, B, and C” means (A), (B), (C), (A and B), (A and C), (B and C), or (A, B and C). For the purposes of the description, a phrase in the form “(A)B” means (B) or (AB) that is, A is an optional element.

The description may use the terms “embodiment” or “embodiments,” which may each refer to one or more of the same or different embodiments. Furthermore, the terms “comprising,” “including,” “having,” and the like, as used with respect to embodiments, are synonymous.

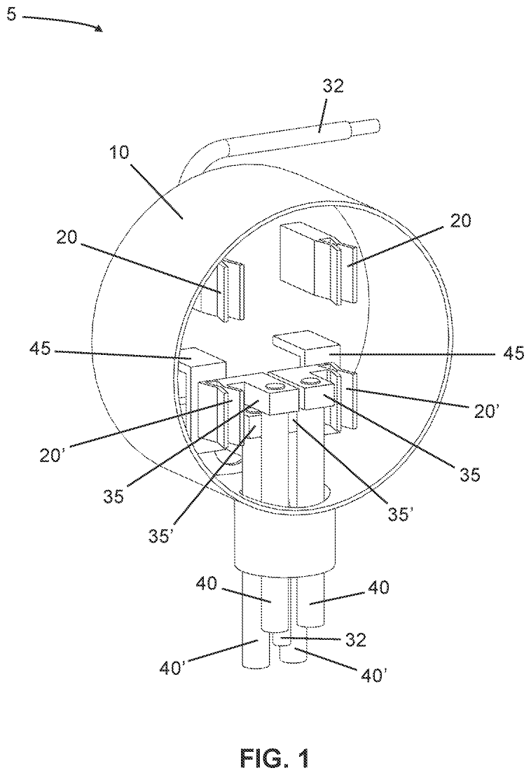

Preferred embodiments of the present invention and their advantages may be understood by referring to FIGS. 1-9, wherein like reference numerals refer to like elements.

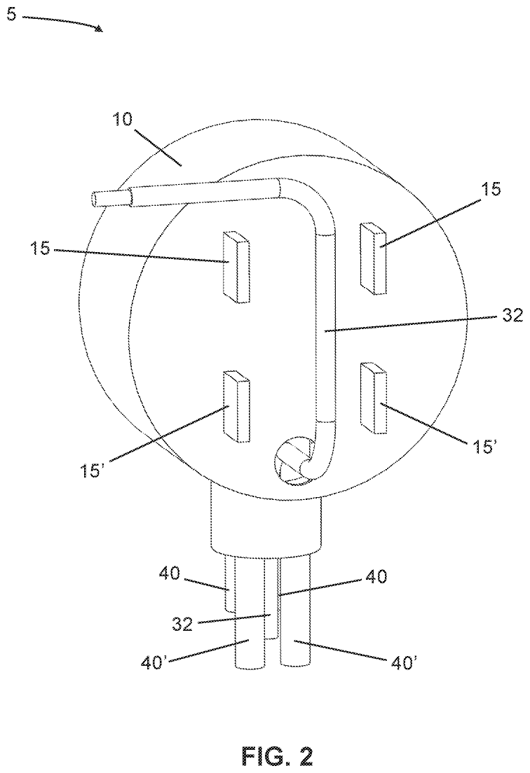

With reference to FIGS. 1-2, device 5 includes housing 10 for containing electrical components. The terms “device”, “interrupt adapter”, “electric meter interrupting device”, “meter interrupting device”, and “MID” are intended to be used herein synonymously, and to include the device shown as 5 and 5′. 5 and 5′ can be used interchangeably herein, unless otherwise noted. In an embodiment, housing 10 is constructed of injection molded plastic. However, one skilled in the art would understand and appreciate that housing 10 could be made in other ways and from alternative materials without deviating from the scope of the invention. Preferably the device 5, 5′ and materials it is made from are weatherized to protect the internal components as the device is designed to be used outside and be exposed to the elements, including snow, rain, and sun. Electrical stabs 15, 15′ and electrical receptacles 20, 20′ are disposed at opposite sides of the device 5. For example, as shown in the figures, stabs 15, 15′ are disposed at the rear of device 5, and receptacles 20, 20′ are disposed at the front of the device 5. Stabs 15, 15′ are constructed and positioned/oriented to mimic metal stabs (not shown) that protrude from the rear side of an electric meter 25. Likewise, receptacles 20, 20′ are constructed and positioned/oriented to mimic electrical panel receptacles 30, 30′ used to receive the electric meter stabs 80, 80′.

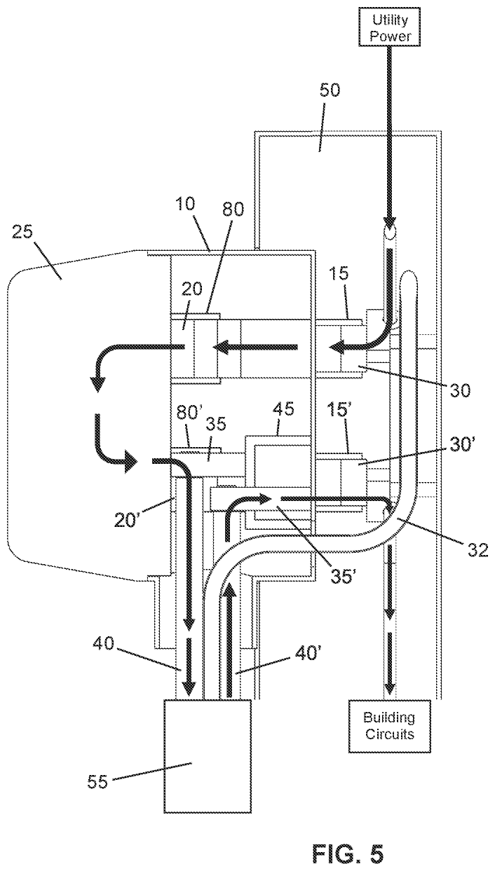

Stabs 15 are each electrically coupled to a corresponding receptacle 20. With reference to FIGS. 1 and 5, the device 5 includes electrical lugs 35, 35′ for coupling electrical wires 40, 40′ to the device 5. Lugs 35 are coupled to mounts 45 and receptacles 20′, and lugs 35′ are electrically coupled to stabs 15′. In a preferred embodiment, mounts 45 are made of an insulating, i.e., non-conductive, material.

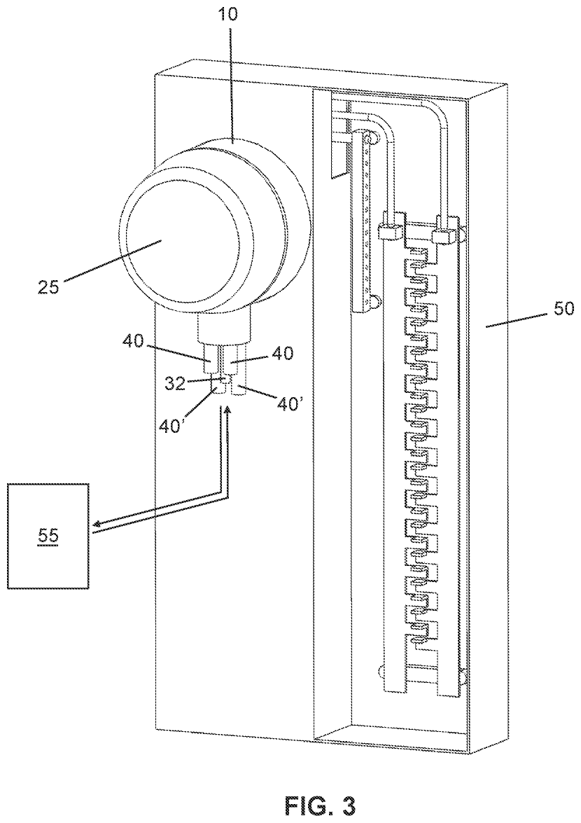

A method of installing the device 5 begins with unplugging the electric meter 25 from the electrical panel 50. Once the electric meter 25 is disconnected, the device 5 is plugged into the place of the electric meter 25 on the electrical panel 50 by inserting stabs 15, 15′ into the electrical panel's electrical receptacles 30, 30′. Once the device 5 is secured to the electrical panel 50, the electric meter 25 is plugged into the device 5 by inserting the electric meter's stabs 80, 80′ into the device's electrical receptacles 20, 20′. FIG. 3 illustrates the device coupled to and in use with the electrical panel 50 and the electric meter 25.

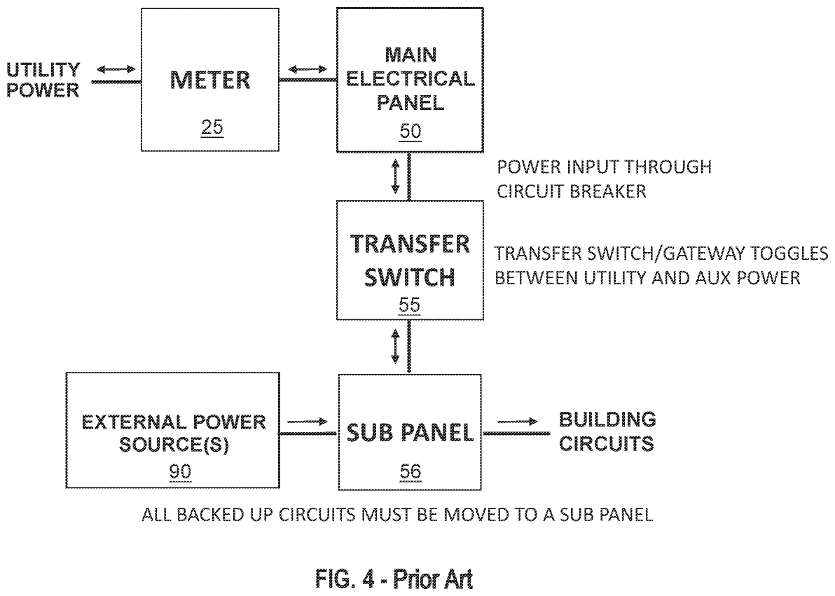

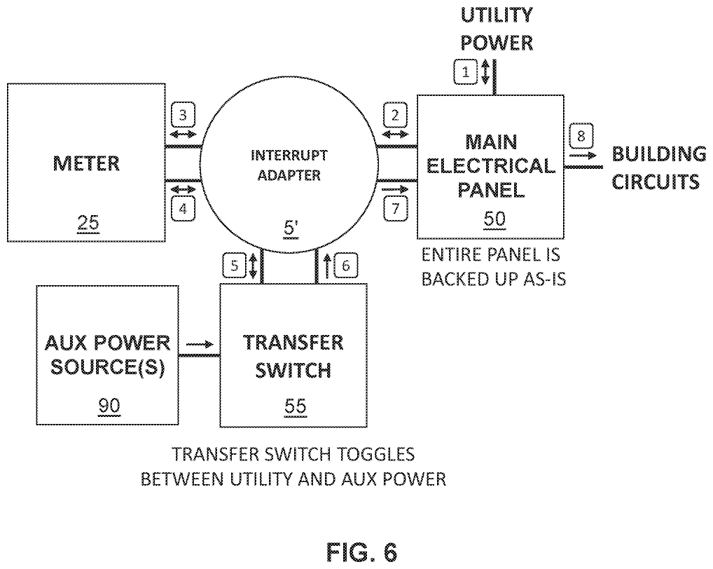

FIG. 4 illustrates the flow of electricity in prior art existing systems using a sub panel 56, i.e., without the device 5. In contrast, FIGS. 5-6 illustrate the flow of electricity, designated by arrows, when the device 5 is used. The numbering in FIG. 6 is used to designate the ordered flow of electricity as it moves through the system. With reference to FIGS. 5-6, electricity from the utility received into the electrical panel 50 is routed into the device 5 via the electric coupling between stabs 15 and electrical panel receptacles 30. The incoming electricity flows straight through the device 5 and into the electric meter 25 via the electric coupling between the electric meter stabs 80 and receptacles 20. The electricity is then routed out of the electric meter 25 and back into the device 5 via the electric coupling between the electric meter stabs 80′ and receptacles 20′. Next, the electricity is routed out of the device 5 via wires 40 to a transfer switch/gateway 55. From the transfer switch/gateway 55, the electricity is routed back into the device 5 via wires 40′. Finally, the electricity is routed back into the electrical panel 50 for distribution via electrical coupling between wires 40′, lugs 35′, stabs 15′, and electrical panel receptacles 30′. With reference to FIGS. 1-3 and 5, a neutral wire 32 is routed through the device 5 to carry the circuit from the transfer switch/gateway 55 to a ground or busbar, typically connected at the electrical panel 50.

As shown in FIG. 6, the transfer switch/gateway 55 can accept additional inputs from renewable and/or backup/auxillary power sources 90, e.g., batteries and solar photovoltaics. Under normal operating, i.e., non-outage, conditions, power from the renewable and/or backup power sources can flow to either the home (or other structure) or to the grid. However, during a power outage, the gateway 55 functions as a transfer switch, disconnecting the grid to prevent back-feed, etc., thereby allowing non-grid power to safely energize the structure, i.e., home or other structure.

By backing up the entire panel, as-is, via interruption of the entire source of the electrical panel prior to the bus bars, the need for adding or transferring circuit breakers is eliminated. The electrical panel cannot be overloaded, because the main breaker still protects it from the incoming power (which now can include power from PV, batteries, generator, etc.), and the loads don't need to be separated from the all-in-one panel because it can be safely disconnected from grid power for backup in case of an outage. Thus, in addition to simplifying the setup process, the present system will never be bound by the bus bar limit constraints of conventional systems, and will never require an electrical panel upgrade or main breaker de-rate, resulting in considerable savings of time and money.

The device 5 is intended for use with “all--in--one” electrical panels, i.e., those panels that house both the electric meter, main breaker, and busbar with branch breakers on it. However, one skilled in the art would understand and appreciate that the device 5 can be employed with any system having an electric meter in electrical communication with an electrical panel. Thus, while material and labor savings would be predominantly realized through use of the device 5 with all-in-one electrical panels, the invention should not be construed as being limited to any particular use/appication.

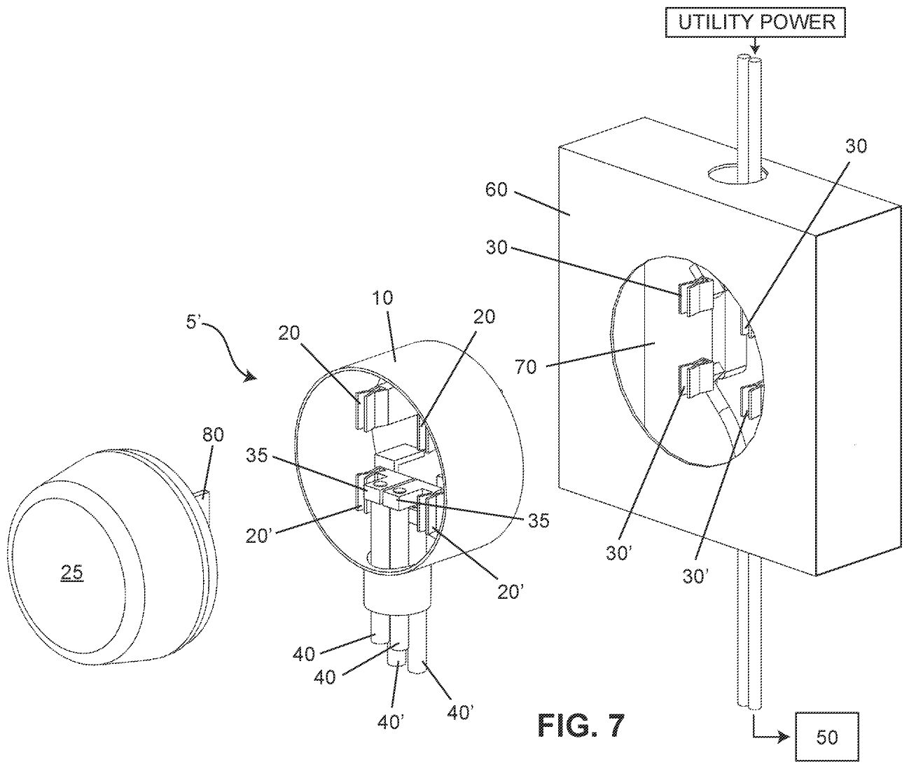

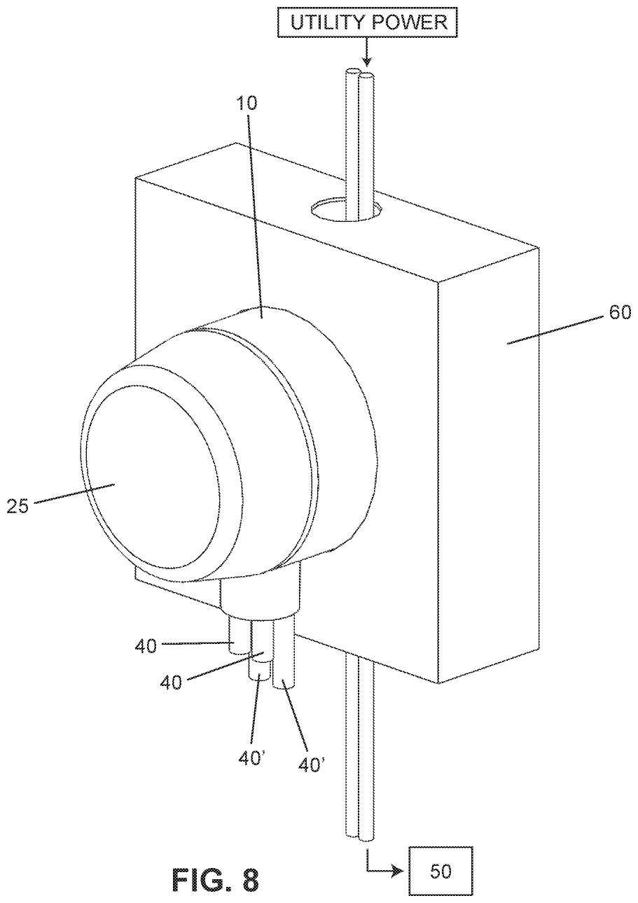

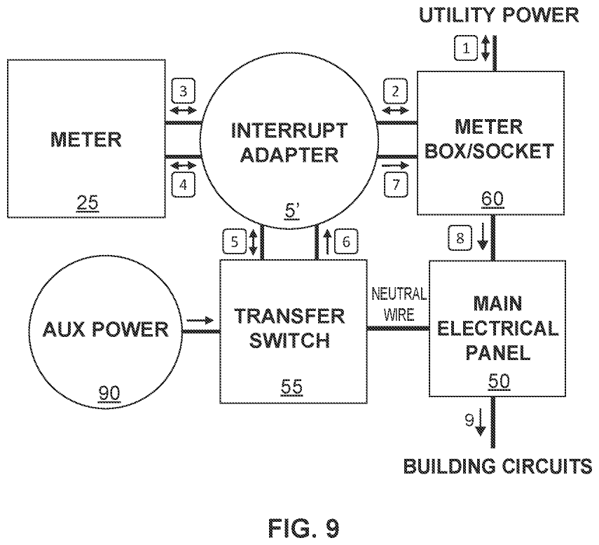

As an example, of a device and methods of using said device, without an all-in-one electrical panel, reference is made to FIGS. 7-9. FIGS. 7 and 8 respectively show an exploded and assembled view of an embodiment of the device 5′ in use with a meter-only box 60 and electric meter 25. Similar to FIGS. 1-3 and 5, the device 5′ is comprises electrical stabs 15 and 15′ and receptacles 20 and 20′ configured to operably couple with the meter socket receptacles 30 and 30′ and electric meter stabs 80 and 80′ respectfully. Under this embodiment the receptacles 30 and 30′ are positioned within a meter socket 70 on a meter-only box 60 instead of a main panel 50. FIG. 9 shows a flow chart that outlines the flow of electricity received into a meter-only box 60 from the utility line, according to an embodiment of the present invention. As shown in FIG. 9 electricity flows into the system from the utility power source (e.g., power grid), through the meter-only box 60, to the device 5′, into the meter 25, back to the device 5′, to the transfer switch, back to the device 5′, back to the meter-only box 60 then to the main panel 50 to power the home/building circuits. The difference between devices 5 and 5′ is that 5′ lacks a neutral wire 32. According to the embodiments of FIGS. 7-9, a neutral wire is used to connect the main panel 50 to the transfer switch 55.

The invention has been described herein using specific embodiments for the purposes of illustration only. It will be readily apparent to one of ordinary skill in the art, however, that the principles of the invention can be embodied in other ways to achieve the same purposes without departing from the scope of the invention. Likewise, it will be readily apparent that the features, functions, elements, and/or steps of the present invention disclosed herein can be used in any combination or order to produce various embodiments of the present invention. This application is intended to cover any adaptations or variations of the embodiments discussed herein. The invention should not be regarded as being limited in scope to the specific embodiments disclosed herein, but instead as being fully commensurate in scope with the following claims.

I claim:

1. An electric meter interrupt device (MID) comprising:
a housing;
a first set of electrical stabs and a second set of electrical stabs disposed at a first side of the housing;
a first set of electrical receptacles and a second set of electrical receptacles disposed at a second side of the housing, wherein the first set of electrical stabs are in electrical communication with the first set of electrical receptacles,
wherein the MID is configured to electrically couple to an outbound pair of electrical wires, each being in electrical communication with a corresponding receptacle of the second set of electrical receptacles, and
wherein the MID is configured to electrically couple to an inbound pair of electrical wires, each being in electrical communication with a corresponding stab of the second set of electrical stabs.

2. The MID of claim 1, wherein the MID is configured to mount between an electrical panel and an electric meter, wherein the MID is configured to receive electricity from the electrical panel, wherein the electricity received into the MID from the electrical panel is routed directly to the electric meter, wherein electricity output by the electric meter is routed through the MID to a transfer switch and then back through the MID to the electrical panel.

3. The MID of claim 1, wherein the first and second set of MID stabs are constructed and oriented to mimic metal stabs that protrude from the rear side of an electric meter such they are configured to operably couple with electrical panel receptacles, and wherein the first and second set of MID receptacles are constructed and oriented to mimic electrical panel receptacles such that they are configured to operably couple and receive the electric meter stabs.

4. The MID of claim 1, wherein the size of each of the inbound wires and outbound wires are selected from the group consisting of 0000 AWG, 000 AWG, 00 AWG, 0 AWG, 1 AWG, 2 AWG, 3 AWG, and 4 AWG.

5. An electric meter interrupt system comprising:
a) a meter socket having receptacles, and positioned within and operably coupled to either a meter-only box or a main panel;
b) an electrical power grid operably coupled to the meter socket;
c) an electrical meter having stabs;
d) an electric meter interrupt device (MID) comprising:
i) a housing;
ii) a first set of electrical stabs and a second set of electrical stabs disposed at a first side of the housing, wherein the first and second set of MID electrical stabs are constructed and oriented to mimic the stabs of the electrical meter, and are operably coupled to the receptacles in the meter socket;
iii) a first set of electrical receptacles and a second set of electrical receptacles disposed at a second side of the housing, wherein the first and second set of MID receptacles are constructed and oriented to mimic the meter socket receptacles, and are operably coupled to the electric meter stabs, and wherein the first set of MID electrical stabs are in electrical communication with the first set of MID electrical receptacles; wherein the second set of electrical receptacles are electrically couple to an outbound pair of electrical wires, each being in electrical communication with a corresponding receptacle of the second set of electrical receptacles, and the second set of electrical stabs are electrically couple to an inbound pair of electrical wires, each being in electrical communication with a corresponding stab of the second set of electrical stabs.

6. The electric meter interrupt system of claim 5, wherein the meter socket is positioned within the main panel that is operably coupled to a building's circuits and the MID is configured to receive electricity from the main panel through its first set of electrical stabs, and then deliver the electricity directly to the electric meter through the MID's first set of receptacles; and wherein electricity output by the electric meter is configured to route back through the MID to a transfer switch via the second set of MID receptacles/outbound pair of electrical wires and then from the transfer switch back through the MID via the second set of MID stabs/inbound pair of electrical wires, and then to the main panel.

7. The electric meter interrupt system of claim 6, wherein the transfer switch is operably coupled to an auxiliary power source and configured such as to either a) allow the electricity from the auxiliary power source to flow to the main panel or back-feed to the grid during non-outage conditions, or b) disconnect the auxiliary power source from the grid during a power outage to prevent back-feed, thereby allowing the auxiliary power to energize the main panel and the coupled building circuits.

8. The electric meter interrupt system of claim 7, wherein the transfer switch ability to connect and disconnect to the grid can be an automatic or manual mechanism.

9. The electric meter interrupt system of claim 7, wherein the auxiliary power source is selected from the group consisting of a solar photovoltaic and a battery.

10. The electric meter interrupt system of claim 5, wherein the meter socket is positioned within the meter-only box which in turn is operably coupled to the main panel that is operably coupled to a building's circuits; and the MID is configured to receive electricity from the meter-only box through its first set of electrical stabs, and then deliver the electricity directly to the electric meter through the MID's first set of receptacles; and wherein electricity output by the electric meter is configured to route back through the MID to a transfer switch via the second set of MID receptacles/outbound pair of electrical wires and then from the transfer switch back through the MID via the second set of MID stabs/inbound pair of electrical wires, and then to the meter-only box and then onto the main panel and the building's circuits.

11. A method of installing a MID comprising:
a) providing a meter socket having receptacles and operably coupled to an electrical power grid and positioned within and operably coupled to either a meter-only box or a main panel;
b) providing an electrical meter having stabs;
c) providing a Meter Interrupt Device (MID) comprising:
i) a housing;
ii) a first set of electrical stabs and a second set of electrical stabs disposed at a first side of the housing, wherein the first and second set of MID electrical stabs are constructed and oriented to mimic the stabs of the electrical meter, such as to operably couple to the receptacles in the meter socket;
iii) a first set of electrical receptacles and a second set of electrical receptacles disposed at a second side of the housing, wherein the first and second set of MID receptacles are constructed and oriented to mimic the meter socket receptacles, such as to operably couple to the electric meter stabs, and wherein the first set of MID electrical stabs are in electrical communication with the first set of MID electrical receptacles; wherein the second set of electrical receptacles are electrically couple to an outbound pair of electrical wires, each being in electrical communication with a corresponding receptacle of the second set of electrical receptacles, and the second set of electrical stabs are electrically couple to an inbound pair of electrical wires, each being in electrical communication with a corresponding stab of the second set of electrical stabs;
d) inserting the MID into the meter socket by coupling the MID stabs into the receptacles of the meter socket; and
e) coupling the electric meter to the MID by coupling the stabs of the electric meter into the receptacles of the MID.

12. The method of installing an MID of claim 11, wherein the meter socket is positioned within the main panel that is operably coupled to a building's circuits and the MID is configured to receive electricity from the main panel through its first set of electrical stabs, and then deliver the electricity directly to the electric meter through the MID's first set of receptacles; and wherein electricity output by the electric meter is configured to route back through the MID to a transfer switch via the second set of MID receptacles/outbound pair of electrical wires and then from the transfer switch back through the MID via the second set of MID stabs/inbound pair of electrical wires, and then to the main panel.

13. The method of installing an MID of claim 12, wherein the transfer switch is operably coupled to an auxiliary power source and configured such as to either a) allow the electricity from the auxiliary power source to flow to the main panel or back-feed to the grid during non-outage conditions, or b) disconnect the auxiliary power source from the grid during a power outage to prevent back-feed, thereby allowing the auxiliary power to energize the main panel and the coupled building circuits.

14. The method of installing an MID of claim 13, wherein the transfer switch ability to connect and disconnect to the grid can be an automatic or manual mechanism.

15. The method of installing an MID of claim 13, wherein the auxiliary power source is selected from the group consisting of a solar photovoltaic and a battery.

16. The method of installing an MID of claim 11, wherein the meter socket is positioned within the meter-only box which in turn is operably coupled to the main panel that is operably coupled to a building's circuits; and the MID is configured to receive electricity from the meter-only box through its first set of electrical stabs, and then deliver the electricity directly to the electric meter through the MID's first set of receptacles; and wherein electricity output by the electric meter is configured to route back through the MID to a transfer switch via the second set of MID receptacles/outbound pair of electrical wires and then from the transfer switch back through the MID via the second set of MID stabs/inbound pair of electrical wires, and then to the meter-only box and then onto the main panel and the building's circuits.
